(19) United States
(12) Patent Application Publication
(10) Pub. No.: US 2011/0147867 A1
(43) Pub. Date: Jun. 23, 2011

(54) METHOD OF VERTICALLY MOUNTING AN INTEGRATED CIRCUIT

(75) Inventors: Jon Slaughter, Tempe, AZ (US); Phillip Mather, Maricopa, AZ (US)

(73) Assignee: EVERSPIN TECHNOLOGIES, INC., Chandler, AZ (US)

(21) Appl. No.: 12/645,749

(22) Filed: Dec. 23, 2009

(51) Int. Cl. H01L 27/20; H01L 21/98; H01L 21/50

(52) U.S. Cl. 257/427; 438/107; 438/106; 438/3; 257/E27.006; 257/E21.705; 257/E21.499

(57) ABSTRACT

A method of mounting a first integrated circuit (102, 500, 704) on one of a circuit board (300, 700) or a second integrated circuit (706), the first integrated circuit (102, 500, 704) formed over a substrate (104) and having a surface (119) opposed to the substrate (104) and a side (122, 530, 930) substantially orthogonal to the surface (119), and including a conductive element (116, 117, 118, 522, 524, 526, 528, 528′, 528″) coupled to circuitry (102, 500, 704) and formed within a dielectric material (120, 518), the one of the circuit board (300, 700) or the second integrated circuit (706) including a contact point (304, 306, 314), the method including singulating (1104) the first integrated circuit (102, 500, 704) to expose the conductive element (116, 117, 118, 522, 524, 526, 528, 528′, 528″) on the side (222, 630, 1030), and mounting (1108) the first integrated circuit (102, 500, 704) on the one of a circuit board (300, 700) or a second integrated circuit (706) by aligning the conductive element (116, 117, 118, 522, 524, 526, 528, 528′, 528″) exposed on the side (222, 630, 1030) to make electrical contact with the contact point (304, 306, 314).

### FIELD

The present invention generally relates to an integrated circuit packaging method and structure and more particularly to a method for vertically mounting an integrated circuit such as a thin-film magnetic field sensor.

### BACKGROUND OF THE INVENTION

A number of integrated circuit mounting methods have evolved over time, including those for dual inline packages (DIP), pin grid arrays (PGA), ball grid arrays (BGA), leadless chip carriers (LCC), and small outline integrated circuits (SOIC) to name a few. Packaging of an integrated circuit provides for its mounting upon a circuit board, for electrical isolation from other integrated circuits, and for protection from exposure to the environment. The integrated circuit contains a plurality of electrical contact pads that are coupled to leads on the circuit board, such as by wire soldered therebetween. The integrated circuit is typically mounted (horizontally) with a substrate adjacent the circuit board and is encapsulated in plastic or ceramic.

Some functions performed by a particular integrated circuit require it to be mounted perpendicular (vertically) to the circuit board. For example, integrated circuits that sense a magnetic field require the sensing of three perpendicular axes (x, y, z directions). Two of the axes (x and y) may be sensed by mounting a sensor (or a plurality of sensors) horizontally on the circuit board for each axis. The third axis (z) may be sensed by mounting a sensor (or a plurality of sensors) vertically.

Hall sensors are generally responsive to out-of-plane field components normal to the substrate surface while thin-film magnetoresistive sensors are responsive to in-plane applied magnetic fields. Utilizing these responsive axes, development of a small footprint three axis sensing solution typically involves a multi chip module with one or more chips positioned orthogonal angles to one another. For magnetoresistive sensors, the orthogonal in-plane components may be achieved with careful sensor design, but the out-of-plane response is commonly garnered through a secondary chip that is mounted vertically with electrical contacts made through some type of vertical bonding, such as solder reflow across the orthogonal contacts. As the size of the vertically bonded chip is typically dominated by the size and pitch of the contact pads, such a technique results in a large vertical extent of the finished package, adds to the die and assembly costs, and makes chip scale packaging difficult and costly. Since magnetic sensors can be produced inexpensively in a very small footprint utilizing magnetic tunnel junction technology, packaging and final test are a significant contributor to the overall cost.

One known method described in U.S. Pat. No. 7,494,920 mounts an integrated circuit on a printed circuit board and couples pads on the integrated circuit to leads on the printed circuit board. The printed circuit board is singulated to expose a via in the printed circuit board. The structure is vertically mounted with the exposed via contacting a contact point on another printed circuit board. However, this vertical mounting adds to the physical dimensions and fabrication complexity of the device.

Accordingly, a need exists for an improved design and fabrication process for vertically mounting an integrated circuit directly on a printed circuit board or directly on another integrated circuit. There is also a need for a three-axis magnetic field sensor that can be efficiently and inexpensively constructed as an integrated circuit structure for use in mobile applications. There is also a need for an improved magnetic field sensor and fabrication to overcome the problems in the art, such as outlined above. Furthermore, other desirable features and characteristics of the present invention will become apparent from the subsequent detailed description and the appended claims, taken in conjunction with the accompanying drawings and this background.

### BRIEF SUMMARY OF THE INVENTION

A method of mounting a first integrated circuit on one of a circuit board or a second integrated circuit, the first integrated circuit formed over a substrate and having a surface opposed to the substrate and a side substantially orthogonal to the surface, and including a conductive element coupled to circuitry and formed within a dielectric material, the one of a circuit board or a second integrated circuit including a contact point, the method including singulating the first integrated circuit to expose the conductive element on the side, and mounting the first integrated circuit on the one of a circuit board or a second integrated circuit by aligning the conductive element exposed on the side to make electrical contact with the contact point.

### BRIEF DESCRIPTION OF THE DRAWINGS

The present invention will hereinafter be described in conjunction with the following drawing figures, wherein like numerals denote like elements, and

FIG. 1 is a cross section of a known integrated circuit;

FIG. 2 is a cross section of the integrated circuit of FIG. 1 singulated to expose a contact pad in accordance with a first exemplary embodiment;

FIG. 3 is a top view of a known circuit board;

FIG. 4 is a top view of the integrated circuit of FIG. 2 vertically mounted on the circuit board of FIG. 3 in accordance with the first exemplary embodiment;

FIG. 5 is a cross section of a magnetic tunnel junction device and a plurality of contact pads;

FIG. 6 is a cross section of the magnetic tunnel junction device of FIG. 5 singulated to expose a plurality of contact pads in accordance with the first exemplary embodiment;

FIG. 7 is a top view of a circuit board having first, second, and third integrated circuits disposed thereon with the first and third integrated circuits mounted in a known manner and the second integrated circuit mounted vertically;

FIG. 8 is a top view of the second integrated circuit mounted on the third integrated circuit of FIG. 7 in accordance with the first exemplary embodiment;

FIG. 9 is a cross section of the magnetic tunnel junction device of FIG. 5 and a via;

FIG. 10 is a cross section of the magnetic tunnel junction device of FIG. 9 singulated to expose a plurality of vias in accordance with a second exemplary embodiment; and

FIG. 11 is a flow chart of the steps of the exemplary embodiments.

### DETAILED DESCRIPTION OF THE INVENTION

The following detailed description is merely exemplary in nature and is not intended to limit the invention or the application and uses of the invention. Furthermore, there is no intention to be bound by any expressed or implied theory presented in the preceding technical field, background, brief summary, or the following detailed description.

In a first exemplary embodiment taught herein, a first integrated circuit, for example a magnetic tunnel junction (MTJ) sensor that exhibits tunneling magnetoresistance, is singulated to expose the side of at least one conductive pad that is coupled to circuitry of the first integrated circuit. The first integrated circuit is then vertically mounted on either a circuit board or a second integrated circuit so the at least one exposed conductive pad of the first integrated circuit contacts at least one contact point on the circuit board or the second integrated circuit. A solder bump is placed on either the conductive pads or the contact points prior to mounting and is reflowed after mounting.

In a second exemplary embodiment, a first integrated circuit, for example an MTJ sensor, is singulated to expose a plurality of vias that are coupled to the sensor. The first integrated circuit is then vertically mounted on a circuit board or a second integrated circuit so each of the plurality of vias uniquely couple to at least one contact point on the circuit board or second integrated circuit. Solder bumps are placed prior to mounting on either the vias or the contact points and reflowed after mounting.

These exemplary embodiments simplify integrated circuit assembly and provide a small package, eliminating the need for bond wires to the perpendicular chip, eliminating the need for a 90 degree bond to the perpendicular chip, and enabling the perpendicular chip to be bonded with pad-to-pad bump technology which can employ smaller pads and smaller pad spacing than the first two options. For small chips with a number of pads, such as magnetic field sensing circuits, reducing the pad area can significantly reduce the total chip area and the total height of the perpendicular chip. The perpendicular chip may be bonded directly on top of another chip or a printed circuit board, minimizing the area occupied by the package, and is expected to have better repeatability of the perpendicular-axis orientation than previously known solutions.

Referring to FIG. 1, the first exemplary embodiment includes an integrated circuit 102 formed on a substrate 104. During fabrication of the integrated circuit 102, each succeeding layer is deposited or otherwise formed in sequence and each circuit element may be defined by selective deposition, photolithography processing, etching, etc. using any of the techniques known in the semiconductor industry. While only one circuit element, transistor 106, is shown, there typically are hundreds or thousands of circuit elements within a single integrated circuit. The transistor 106 has a gate 108 spaced between a drain 110 and a source 112, which are all disposed on a dielectric layer 113 in a well known manner. The source 112 is coupled by a conductive line 114 to a pad 116. Additional pads 117 and 118 are coupled to additional circuit elements (not shown) within the integrated circuit 102. While the pads 116, 117, 118 are shown to be flush with the surface 119 of the dielectric material 120, the pads 116, 117, 118 may alternatively be disposed within the dielectric material 120 and spaced from the surface 119.

In the exemplary embodiment, the dielectric material 120 may be silicon oxide, silicon nitride (SiN), silicon oxynitride (SiON), a polyimide, or combinations thereof. The conductive line 114 and pads 116, 117, 118 may be copper, tantalum, tantalum nitride, silver, gold, aluminum, platinum, or another suitable conductive material. The gate 108, drain 110, and source 112 may comprise any one of the aforementioned conductive materials.

During fabrication of the integrated circuit 102, each succeeding layer is deposited or otherwise formed in sequence and circuit element 106 may be defined by selective deposition, photolithography processing, etching, etc. using any of the techniques known in the semiconductor industry.

The side 122 of the structure 100 is singulated (typically referred to as a saw method) to expose the pads 116, 117, 118 along the new side 222 (see FIG. 2).

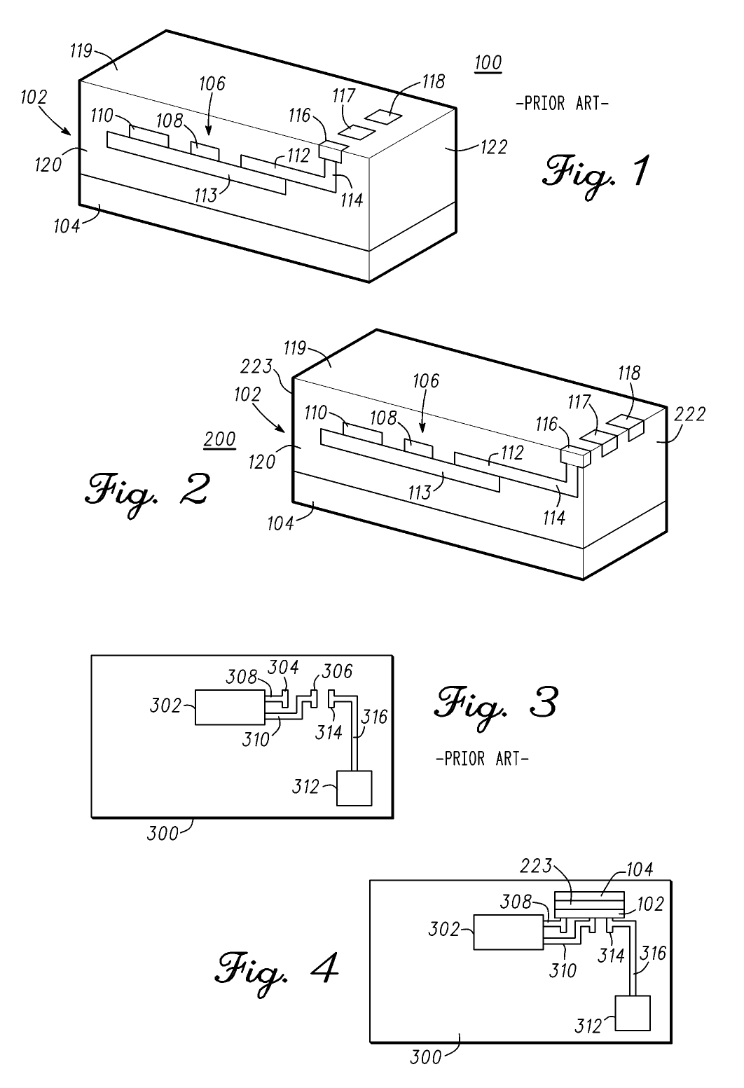

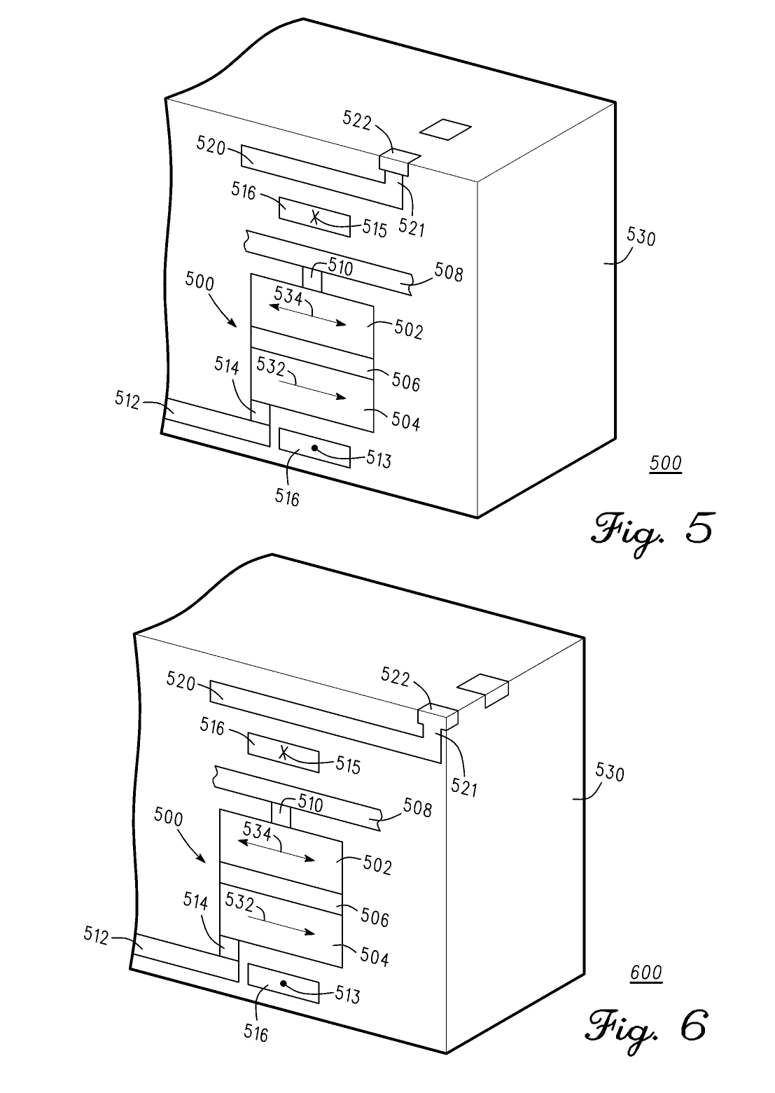

Referring to FIG. 3, a circuit board 300 includes a first integrated circuit 302 coupled to contact points 304 and 306 by traces 308 and 310, respectively. A second integrated circuit 312 is coupled to a contact point 314 by a trace 316. The side 222 of structure 200 (FIG. 2) is mounted (FIG. 4) on the circuit board 300 by aligning the pads 116, 117, 118 to contact the contact points 304, 306, 314, respectively (side 223 faces away from the circuit board 300).

FIGS. 5 and 6 illustrate how magnetic tunnel junction (MTJ) sensor integrated circuits may be singulated to expose contact pads on a side of the integrated circuit for mounting on another integrated circuit or a printed circuit board. Sensors are widely used in modern systems to measure or detect physical parameters, such as position, motion, force, acceleration, temperature, pressure, etc. Inexpensive low-field magnetic sensors, such as those used in an electronic compass and other similar magnetic sensing applications, have been obtainable with MTJ technology. MTJ sensors provide for minimal sensor size and cost.

Referring to FIG. 5, the integrated circuit 102 is an integrated MTJ device 500 formed within a dielectric material 518 and includes a ferromagnetic sense layer 502 and a fixed ferromagnetic region 504 separated by a tunnel barrier 506. During fabrication of the integrated magnetic tunnel device 500, each succeeding layer is deposited or otherwise formed in sequence and each circuit element may be defined by selective deposition, photolithography processing, etching, etc. using any of the techniques known in the semiconductor industry. While only one integrated magnetic tunnel device 500 is shown, there typically are hundreds or thousands of these sensors within a single integrated circuit. The sense layer 502 is coupled to a first conductive line 508 by a via 510, and the fixed region 504 is coupled to a second conductive line 512 by a via 514. A stabilization line (current carrying line) 516 is positioned on opposed sides of the magnetic tunnel device 500 near both the sensor layer 502 and the fixed region 504. The direction of the current 515 is represented by the “X” 515 as going into the page and by the “dot” 513 as coming from the page, though the direction could be reversed. Although the stabilization line 516 is shown to be near both the sense layer 502 and the fixed region 504 in accordance with the preferred embodiment, it should be understood that it may be positioned on only one side of the magnetic tunnel device 500 near either the sense layer 502 or the fixed region 504.

The fixed magnetic region 504 is well known in the art, and conventionally includes a fixed layer (not shown) disposed between the tunnel barrier and an anti-ferromagnetic coupling spacer layer (not shown). The anti-ferromagnetic coupling spacer layer is formed from any suitable nonmagnetic material, for example, at least one of the elements Ru, Os, Re, Cr, Rh, Cu, or their combinations. A pinned layer (not shown) is disposed between the anti-ferromagnetic coupling spacer layer and an optional pinning layer. The sense layer 502 and the fixed layer may be formed from any suitable ferromagnetic material, such as at least one of the elements Ni, Fe, Co, B, or their alloys as well as so-called half-metallic ferromagnets such as NiMnSb, PtMnSb, Fe₃O₄, or CrO₂. The tunnel barrier 506 may be insulator materials such as AlOx, MgOx, RuOx, HfOx, ZrOx, TiOx, or the nitrides and oxidinitrides of these elements.

The ferromagnetic fixed and pinned layers each have a magnetic moment vector that are usually held anti-parallel by the anti-ferromagnetic coupling spacer layer resulting in a resultant magnetic moment vector 532 that is not free to rotate and is used as a reference layer. The sense layer 502 has a magnetic moment vector 534 that is free to rotate in the presence of a magnetic field. In the absence of an applied field, magnetic moment vector 534 is oriented along the anisotropy easy-axis of the sense layer.

A self test line 520 is deposited above the stabilization line 516 and separated therefrom by the dielectric material 518. The self test line 520 is a metal layer, preferably aluminum, that generates a magnetic field when a current is passed therethrough. The self test line 520 may be deposited when a contact pad 522 is deposited, thereby saving process steps. The contact pad 522 typically is aluminum. Another integrated magnetic tunnel junction sensor (not shown) adjacent to the integrated magnetic tunnel junction sensor 500 is coupled to the contact pad 522′. Additional contact pads may be coupled to other elements within the MTJ sensor 500, but are not shown for simplicity of illustration.

In another embodiment, the self test line may be routed on two separate metal layers, in a similar fashion to the stabilization line previously mentioned, whereby current moves in opposing directions on the two different layers. A via (not shown) may connect the current carrying line 526 to this lower metal level.

The dielectric material 518 may be silicon oxide, silicon nitride (SiN), silicon oxynitride (SiON), a polyimide, or combinations thereof. The conductive lines 508, 512, vias 510, 514, 521, stabilization line 516, current carrying line 526, and pad 522 are preferably copper, but it will be understood that they may be other materials such as tantalum, tantalum nitride, silver, gold, aluminum, platinum, or another suitable conductive material.

During fabrication of the magnetic tunnel device 500, each succeeding layer is deposited or otherwise formed in sequence and each magnetic tunnel device 500 may be defined by selective deposition, photolithography processing, etching, etc. using any of the techniques known in the semiconductor industry. During deposition of at least the ferromagnetic sensor 502 and fixed region 504, a magnetic field is provided to set a preferred anisotropy easy-axis (induced intrinsic anisotropy). The provided magnetic field creates a preferred anisotropy easy-axis for magnetic moment vectors 532, 534. In addition to intrinsic anisotropy, sense elements having aspect ratios greater than one may have a shape anisotropy, and the combination of this shape and the intrinsic anisotropy define an easy axis that is preferably parallel to a long axis of the sense element. This easy axis may also be selected to be at about a 30 to 90 degree angle, with the reference magnetization 532. In the bridge embodiment with no flux concentrators, this is preferably at about a 45-degree angle.

The side 530 of the integrated circuit structure 500 is singulated to expose the contact pads 522, 522′ along the new side 630 (see FIG. 6). The integrated circuit 500 may then be rotated ninety degrees for mounting the side 630 and contact pads 522, 522′ onto the printed circuit board similar to that shown in FIG. 4. Note that the integrated circuit 102 of FIGS. 1, 2, and 4, including the MTJ 500 of FIGS. 5, 6 may be mounted onto another integrated circuit instead of a printed circuit board as is shown for the second exemplary embodiment subsequently described herein.

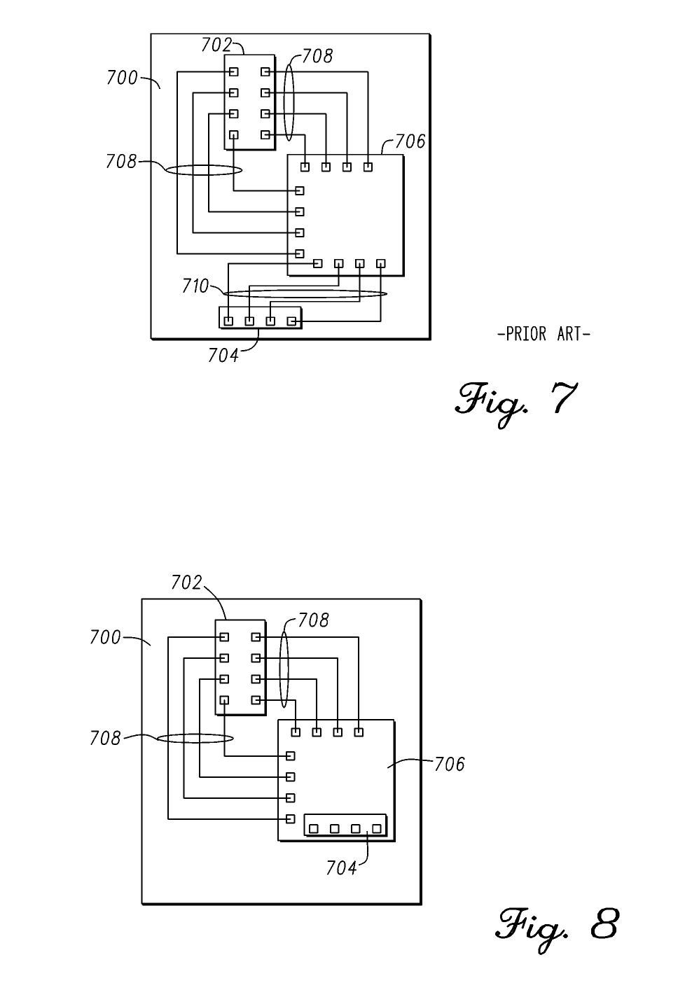

Referring to FIG. 7, a previously known circuit board 700 includes a first integrated circuit 702, such as an X-Y axis MTJ sensor, a second integrated circuit 704, such as Z axis MTJ sensor (mounted perpendicular to the circuit board 700), and a third integrated circuit 706, such as a processor chip. The third integrated circuit 706 is coupled to the first integrated circuit 706 by traces 708 and to the second integrated circuit by traces 710. FIG. 8 illustrates how the second integrated circuit 704, singulated in accordance with the integrated circuit 600, may be mounted onto the third integrated circuit 706, thereby simplifying integrated circuit assembly and providing a small package, eliminating the need for bond wires to the perpendicular chip, eliminating the need for a 90 degree bond to the perpendicular chip, and enabling the perpendicular chip to be bonded with pad-to-pad bump technology which can employ smaller pads and smaller pad spacing than the first two options. When only two chips are required, the printed circuit board may be eliminated by bonding the vertical chip directly on top of the other chip. Additionally, the first and third integrated circuit may be combined monolithically onto a single chip, and the second perpendicular integrated circuit may be mounted vertically thereupon.

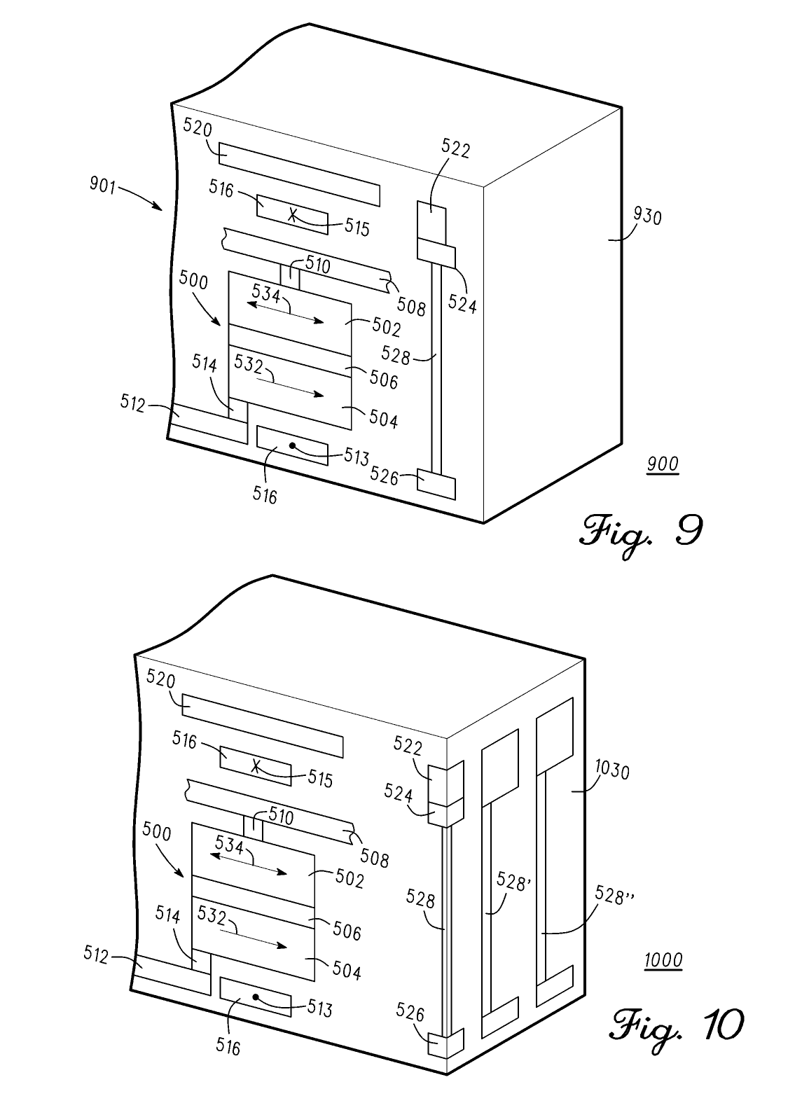

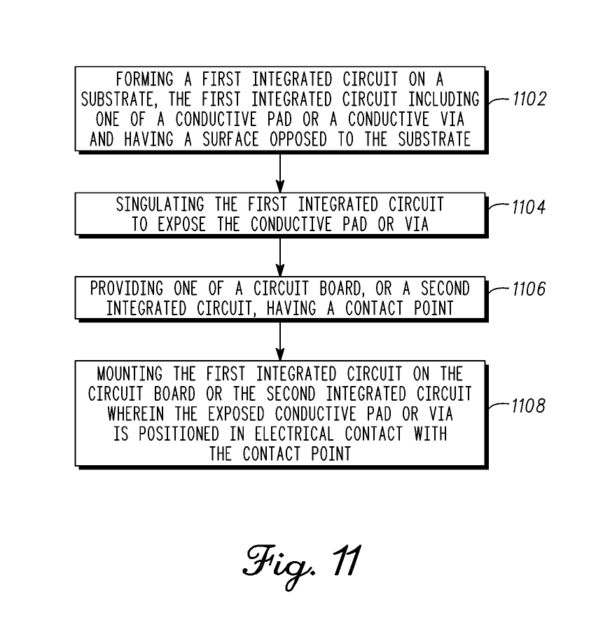

Referring to FIG. 9, in accordance with a second exemplary embodiment, an integrated circuit, such as the MTJ sensor 500 as previously described with respect to FIG. 5, has the stabilization line 116 deposited at the same time as pads 124. The contact pad 122 typically is a termination metal, e.g., aluminum, of a copper pad 124. The copper pad 124 may be coupled, for example, to a current carrying line 126 by a via 128. The side 830 of the structure 1000 is singulated to expose the vias 828, 828′, 828″ along the new side 1030 (see FIG. 10). The structure 1000 may then be rotated to place the side 1030 and the vias 528, 528′, and 528″ onto either a printed circuit board or another integrated circuit.

FIG. 11 is a flow chart of the steps of vertically mounting an integrated circuit on a printed circuit board including forming 1102 a first integrated circuit on a substrate, the first integrated circuit including at least one of a conductive pad and a conductive via and having a surface opposed to the substrate, and having a side. The integrated circuit is singulated 1104 to expose a portion (the original side or a new side) of the conductive pad. A circuit board, or a second integrated circuit, having a contact point is provided 1106 and the integrated circuit is mounted 1108 on the circuit board or the second integrated circuit wherein the exposed conductive pad or via is positioned in electrical contact with the contact point.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments, it being understood that various changes may be made in the function and arrangement of elements without departing from the scope of the invention as set forth in the appended claims and the legal equivalents thereof.

1. A method of mounting a first integrated circuit on one of a circuit board or a second integrated circuit, the first integrated circuit formed over a substrate and having a surface opposed to the substrate and a side substantially orthogonal to the surface, and including a conductive element coupled to circuitry and formed within a dielectric material, the one of a circuit board or a second integrated circuit including a contact point, comprising:
singulating the first integrated circuit to expose the conductive element on the side; and
mounting the first integrated circuit on the one of a circuit board or a second integrated circuit by aligning the conductive element exposed on the side to make electrical contact with the contact point.

2. The method of claim 1 wherein the conductive element includes a via.

3. The method of claim 1 wherein the conductive element is a contact pad.

4. The method of claim 1 further comprising:
placing solder between each of the conductive elements and the contact points; and
reflowing the solder.

5. The method of claim 1 wherein the first integrated circuit comprises a magnetoresistive sensor.

6. The method of claim 1 wherein the first integrated circuit comprises a plurality of magnetic tunnel junction devices.

7. The method of claim 1 further comprising, following the singulating step and before the mounting step, plating a noble metal onto the exposed conductive element to create good surface energies and stability from oxidation for optimal solder reflow.

8. A method of mounting a first integrated circuit on one of a circuit board or a second integrated circuit, the first integrated circuit including a plurality of circuit elements each coupled to one of a plurality of conductive elements, the circuit elements and conductive elements formed within a dielectric material, and the circuit board or the second integrated circuit including a plurality of conductive contact points, comprising:
singulating the first integrated circuit on a side orthogonal to a plane of the substrate to expose at least a portion of each of the conductive elements; and
mounting the first integrated circuit on the circuit board or the second integrated circuit by aligning one each of the exposed portions of the conductive elements with one of the plurality of conductive contact points.

9. The method of claim 8 wherein each of the conductive elements includes a via.

10. The method of claim 8 wherein each of the conductive elements is a contact pad.

11. The method of claim 8 wherein the first integrated circuit comprises a magnetoresistive sensor.

12. The method of claim 8 wherein the first integrated circuit comprises a plurality of magnetic tunnel junction devices.

13. The method of claim 8 further comprising, following the singulating step and before the mounting step:
plating a noble metal onto the exposed conductive element to create good surface energies and stability from oxidation for optimal solder reflow.

14. An electronic circuit, comprising:
one of a printed circuit board or a first integrated circuit including a plurality of conductive contact points; and
a second integrated circuit comprising:
a substrate;
a dielectric material formed on the substrate and having a surface opposed to the substrate and a side substantially orthogonal to the surface;
a plurality of circuit elements formed within the dielectric material;
a plurality of conductive elements formed within the dielectric material, each of the conductive elements coupled to one of the circuit elements, wherein the conductive elements are exposed at the side of the dielectric material, the side of the second integrated circuit is mounted upon one of the printed circuit board or the first integrated circuit, and one each of the conductive elements are aligned with and conductively coupled to one of the conductive contact points.

15. The electronic circuit of claim 14 wherein the conductive element comprises:
a via.

16. The electronic circuit of claim 14 wherein the conductive element comprises:
a contact pad.

17. The electronic circuit of claim 14 wherein the second integrated circuit comprises a magnetoresistive sensor.

18. The electronic circuit of claim 14 wherein each of the plurality of circuit elements comprise:
a magnetic field sensor including:
first and second current carrying lines formed within the dielectric material;
a stabilization line formed within the dielectric material;
a first magnetic tunnel junction sensing element coupled between the first and second current carrying lines, and adjacent to the stabilization line; and
a magnetic field generating line positioned adjacent the first magnetic tunnel junction sensing element;
wherein each of the conductive elements exposed on the side of the integrated circuit are coupled to one of the first and second current carrying lines.

19. The electronic circuit of claim 14 wherein the first magnetic tunnel junction sensing element comprises:
an array of magnetic tunnel junction elements.

20. The sensor of claim 14 further comprising:
second, third, and fourth magnetic tunnel junction sensing elements configured, in conjunction with the first magnetic tunnel junction sensing element, as a Wheatstone bridge.
